(19) United States
(12) Patent Application Publication
(10) Pub. No.: US 2004/0160744 A1
(43) Pub. Date: Aug. 19, 2004

(54) CASING STRUCTURE FOR POWER SUPPLY

(76) Inventors: Yi-Cheng Yuan, Miao-Li County (TW); Yung-Chuan Tseng, Miao-Li County (TW)

Correspondence Address: NAIPO (NORTH AMERICA INTERNATIONAL PATENT OFFICE), P.O. BOX 506, MERRIFIELD, VA, 22116, US

(21) Appl. No.: 10/708,195

(22) Filed: Feb. 15, 2004

(30) Foreign Application Priority Data
Feb. 19, 2003 (TW) 092202858

(51) Int. Cl. H05K 5/00

(52) U.S. Cl. 361/724

(57) ABSTRACT

A casing structure for a power supply mainly includes an upper casing body and lower casing body. A pair of inlaying sheets and a plurality of the engaging edges are respectively formed at the flank sides of the upper casing body and engaged edges and an inlayed slot are respectively disposed at the flank sides of the lower casing body corresponding to the engaging edges and the inlaying sheets. Whereby, the upper casing body and the lower casing body are overlapped connecting with each other. Furthermore, an arc notch with an inward contracted opening is disposed at the lower casing body so as to be convenient in wiring arrangement and to prevent internal wires from bundling. And, an inlaying fixation manner is used to allow simplifying an assembly procedure for a casing.

### BACKGROUND OF INVENTION

1. Field of the Invention

The present invention relates to a casing structure, and more particularly to a casing structure for a power supply.

2. Description of the Prior Art

Please refer to FIGS. 1 and 2. A casing 10 for a power supply of the prior art comprises a lower seat 11 and an outer cover 12. The lower seat 11 is formed as a “U” type body by bending two side plates 112A and 112B upward to be perpendicular to a bottom plate 111 at the two flank sides of the bottom plate 111. And, two plate strips 113A and 113B are respectively disposed perpendicularly at another two flank sides of the bottom plate 111 to cause to form four slides 114 respectively between the plate strips 113A, 113B and the side plates 112A, 112B. Screw holes 115 are respectively disposed at the free end faces of the side plates 112A, 112B. And, the outer cover 12 is formed as a “∩” type body by bending the side plate 122A, 122B downward to be perpendicular to a top plate 121 at the two flank sides of the top plate 121. Therefore, a PCB and electric elements (not shown in the figures) are installed in the lower seat 11 of the casing 10 and a through hole 116 is opened on the lower seat 11 for internal wires to be passed through.

Please refer to FIG. 2 again. First, pass internal wires through the hole 116 in an assembly procedure. And then, slide the free ends of the side plates 122A and 122B of the outer cover 12 into the lower seat 11 along the slides 114. Finally, screw screws 13 into screw holes from above the outer cover 12 so as to assemble those parts into the casing 10.

However, the hole 116 is used for the wiring outlet for the internal wires to pass out through. Therefore, the internal wires needs to be bundled together first in an extraordinary procedure so as to pass out through the hole 116 easily. Otherwise, the hole 116 needs to be enlarged to be convenient for the internal wires to be passed out through, but it lowers an electromagnetic interference (EMI) shielding effect. Besides, that the screws are used to fix the assembly of the outer cover 12 and the lower seat 11 increases an assembly time.

### SUMMARY OF INVENTION

One object of the present invention is to provide a casing structure for a power supply; a simplified assembly procedure can be attained to by disposition of a wiring outlet at a lower casing body and inserting fixation manner.

Another object of the present invention is to provide a casing structure; a wiring arrangement can be processed conveniently and the dimension of a wiring outlet is not needed to increase through a wiring outlet with an arc notch and inward contracted opening. And, connecting a upper casing body and lower casing by overlapping each other can increase electromagnetic shielding effect.

For attaining to the objects mentioned above, a casing structure for a power supply mainly comprises a upper casing body and a lower casing body. A pair of inlaying sheets and a plurality of engaging edges are formed at the flank sides of the upper casing body and inlayed slots and engaged edges are respectively disposed at the flank sides of the lower casing body corresponding to the inlaying sheets and the engaging edges so as to allow forming a close parallelepiped body by overlapping engaging the upper casing body and the lower casing body with each other. Besides, a wiring outlet with an arc notch and inward contracted opening are further disposed at the lower casing body in favor of wiring arrangement.

### BRIEF DESCRIPTION OF DRAWINGS

The present invention can be more fully underby reference to the following description and accompanying drawings, in which:

FIG. 1 is a prospective view, showing a casing structure for a power supply of the prior art after assembly;

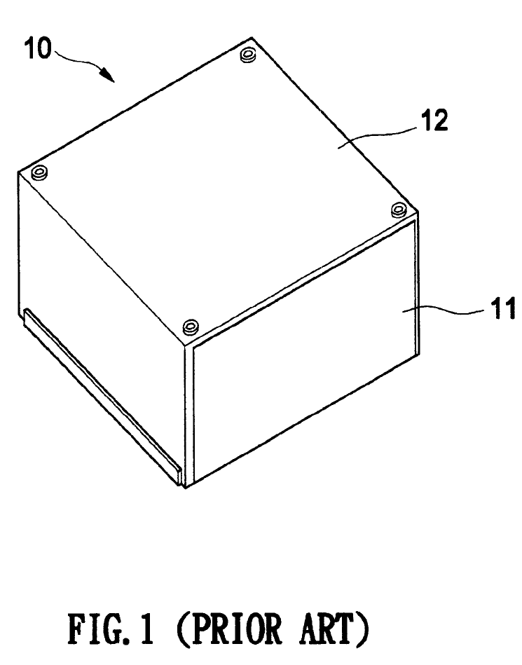

FIG. 2 is an explosive view, showing parts of a casing structure for a power supply of the prior art;

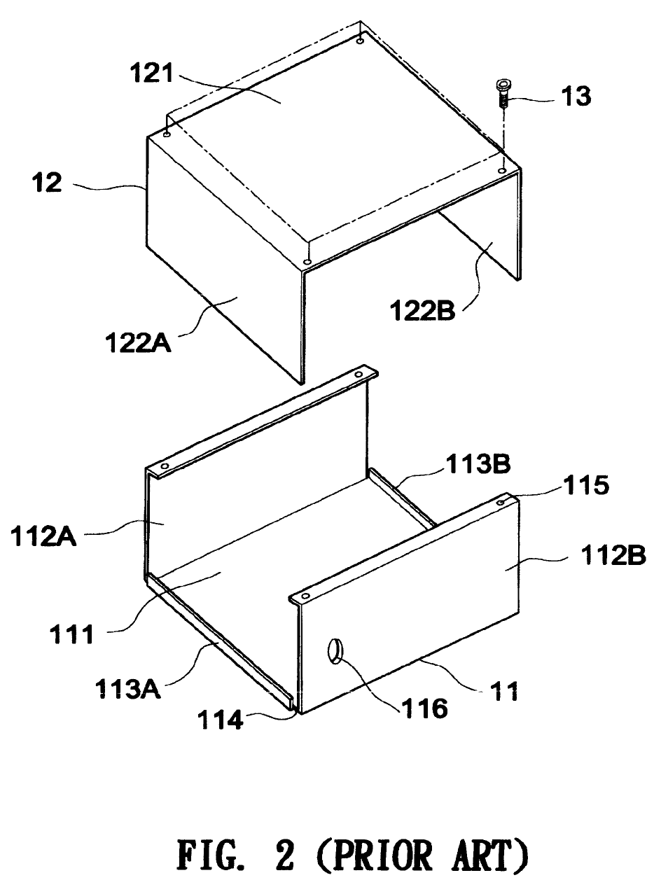

FIG. 3 is a prospective view, showing a casing structure for a power supply according to the present invention after assembly; and

FIG. 4 is an explosive view, showing parts of a casing structure for a power supply according to the present invention.

### DETAILED DESCRIPTION

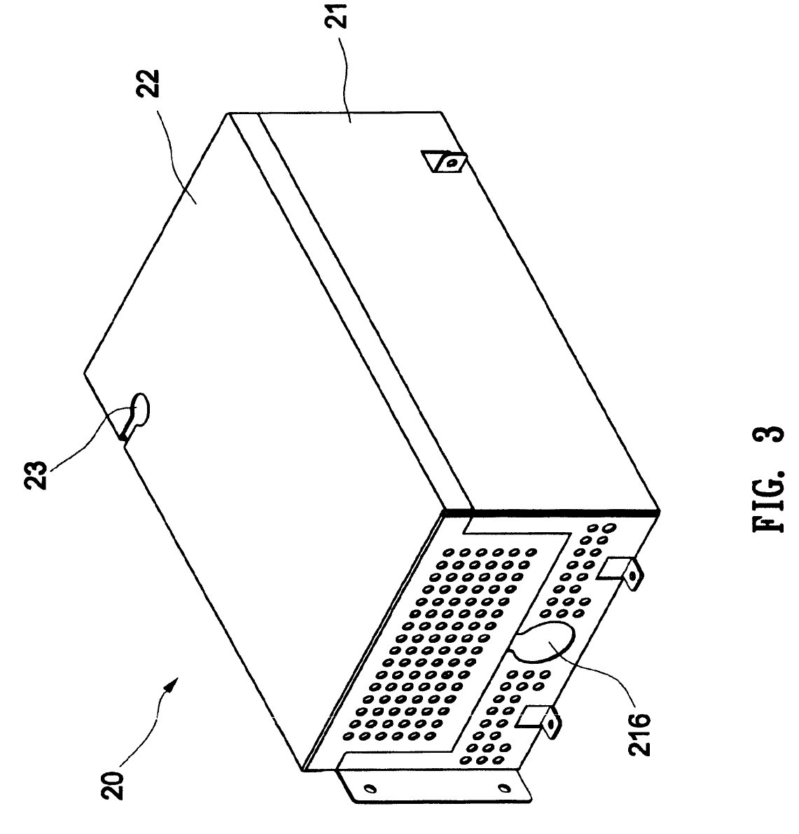

Please refer to FIG. 3. A casing 20 comprises a lower casing body 21 and an upper casing body 22.

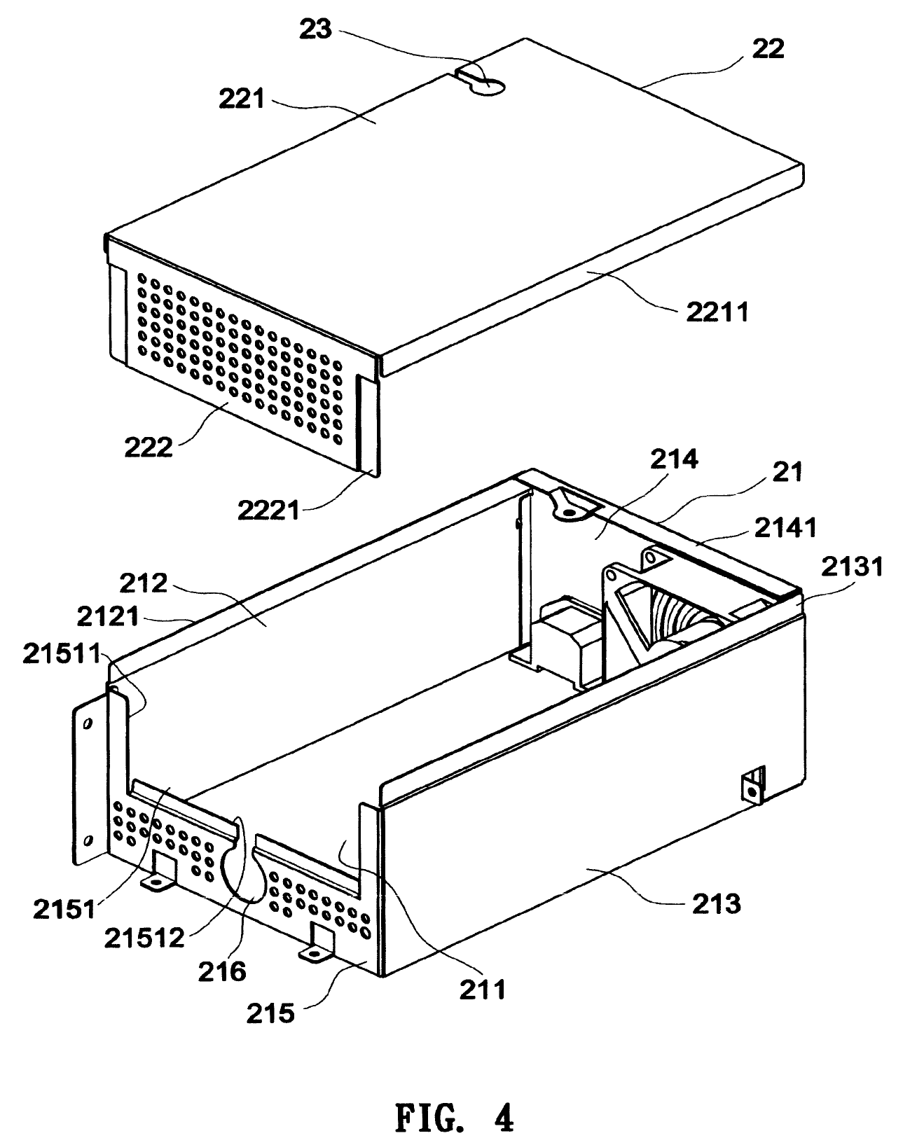

Please refer to FIG. 4. The lower casing body consists of a bottom plate 211, and a first side plate 212, second side plate 213, third side plate 214 and fourth side plate 215 respectively disposed perpendicularly to the four flank sides of the bottom plate 211. The first side plate 212 and the second side plate 213 are faced to each other and the free ends of theirs are extended with inward indented engaged edges 2121 and 2131. The third side plate 214 and the fourth side plate are faced to each other, and an engaged edge 2141 is formed by bending the free end of the third side plate 214 perpendicularly so as to allow the free ends of the first side plate 212, the second side plate 213 and the third side plate 214 are located at a same plane for a top plate 221 of the upper casing body 22 to be leaned on them while assembling. A rectangular notch 2151 is disposed at the free end of the fourth side plate 215 and a pair of elastic sheets 21511 and a pair of sheets 21512 are respectively disposed at the two sides and the bottom of the notch 2151. The elastic sheets can be formed into one body with the side plate by pressing. The two elastic sheets at the flank sides of the notch 2151 are disposed at the same plane with the two flank sides of the fourth side plate 215. The elastic sheets at the bottom of the notch 2151 are indented inward to form a groove between them and the elastic sheets 21511 at the two flank sides so as to allow the notch 2151 to form an inlayed slot. A wiring outlet 216 communicated with the engaged notch is disposed at the bottom of the engaged notch as an outlet for internal wires. The wiring outlet 216 can be an arc notch and the opening thereof is contracted inward toward the inlayed slot.

The upper casing body 22 is formed according to the shape of the opening of the lower casing body 21 so as to be assembled into the closed casing 20. The upper casing body 22 comprises a top plate 221. Engaging edges 2211 are bent downward at the two flank sides of the top plate 221. The two engaging edges 2211 are engaged closely respectively with the engaged edges 2121 and 2131 of the first side plate 212 and the second side plate 213. A side plate 222 is extended downward perpendicularly at a flank side of the top plate 221 corresponding to the fourth side plate 215. The side plate 222 is formed according to the shape of the notch 2151 so as to shield the lower casing body 21. A pair of inlaying sheets 2221 are disposed respectively at the two flank sides of the side plate 222. The inlaying sheets 2221 are inserted into the notch 2151 of the lower casing body 21.

An assembly procedure according to the present invention is to process wiring arrangement first. And then, place internal wires into the wiring outlet 216 from the inward contracted opening thereof and the internal wires are accepted therein. Next, push the upper casing body 22 to the lower casing body 21 after the inlaying sheets 2221 of the upper casing body 22 are aimed at the notch 2151. The upper casing body 22 is pressed to fix and combine with the lower casing body 21 to form a close parallelepiped body, because a clamping force yielded from the elastic sheets 21511 and 21512 at the flank sides of the notch 2151 acts on the inlaying sheets 2221. Besides, the inward contracted opening of the wiring outlet can prevent the accepted wires from leaking out, and the outlet 216 can be closed after the upper casing body is assembled in. Therefore, because an opening is disposed at the outlet 216, wires can be placed in the outlet 216 conveniently from the opening, and then close the outlet 216 by inlaying and fixing the upper casing body 22 so that wires can be entered the outlet without processing a wiring arrangement. Moreover, screws are not needed in the whole assembly process; the process is simplified.

Furthermore, because wires can be placed in the outlet 216 directly and conveniently through the arc notch, it does not need to increase the diameter of the outlet 216 in order to enter the wires conveniently and the diameter of an outlet is decided according to the number of wires only so that electromagnetic interference shielding effect is not influenced. Also, an outlet such as an outlet 23 on the upper casing body 22 can be disposed at a location for wires to be easily pulled out. When the lower casing body 21 is combined with the upper casing body 22, the engaging edges 2211 at the two flank sides of the top plate 221 of the upper casing body 22 are respectively accepted in the indentions beside the engaged edges 2121 and 2131 so as to allow them to be overlapped closely with the engaged edges 2121 and 2131. And, the inlaying sheets 2221 at the two flank sides of the side plate 222 of the upper casing body 22 are respectively overlapped with the elastic sheets 21511 and 21512. Also, another end of the top plate 222 is leaned on the engaged edge 2141 of the third side plate 214 so as to overlap with each other. Therefore, the engagement faces are all overlapped with each other after the upper casing body 22 and the lower casing body 21 are assembled together. Whereby, a sealing performance can be better and an electromagnetic shielding effect is enhanced.

It is noted that the casing structure for a power supply described above is the preferred embodiment of the present invention for the purpose of illustration only, and are not intended as a definition of the limits and scope of the invention disclosed. Any modifications and variations that may be apparent to a person skilled in the art are intended to be included within the scope of the present invention.

1. A casing structure for a power supply, mainly comprising a upper casing body and said lower casing body; wherein a pair of inlaying sheets and a plurality of engaging edges are respectively formed at the flank sides of said upper casing body and engaged edges and an inlayed slot are respectively disposed at the flank sides of said lowercasing body corresponding to said engaging edges and said inlaying sheets, whereby, said upper casing body and said lower casing body are overlapped connecting with each other.

2. The casing structure according to claim 1, wherein a wiring outlet is dispose at said lower casing body.

3. The casing structure according to claim 1, wherein a wiring outlet is disposed at said upper casing body.

4. The casing structure according to claim 2, where said wiring outlet is an arc notch with an inward contracted opening.

5. The casing structure according to claim 3, wherein said wiring outlet is an arc notch with an inward contracted opening.

6. The casing structure according to claim 1, wherein a plurality of elastic sheets are disposed around said engaged notch and said inlaying sheets are inserted between said elastic sheets.

7. The casing structure according to claim 1, wherein said lower casing body and said upper casing body are assembled to form a close parallelepiped body.
